(19) United States
(12) Patent Application Publication
(10) Pub. No.: US 2023/0198665 A1
(43) Pub. Date: Jun. 22, 2023

(54) BACKWARD-COMPATIBLE FORWARD ERROR CORRECTION METHOD AND SYSTEM FOR BURST ERRORS AND ERASURES

(71) Applicant: KONE CORPORATION, Helsinki (FI)

(72) Inventors: Gergely HUSZAK, Helsinki (FI); George ZIMMERMAN, Helsinki (FI)

(73) Assignee: KONE CORPORATION, Helsinki (FI)

(21) Appl. No.: 18/108,306

(22) Filed: Feb. 10, 2023

Related U.S. Application Data
(63) Continuation of application No. PCT/IB2021/057420, filed on Aug. 11, 2021.
(60) Provisional application No. 63/064,822, filed on Aug. 12, 2020.

(51) Int. Cl. H04L 1/00

(52) U.S. Cl. CPC H04L 1/0057; H04L 2001/0094

(57) ABSTRACT

An aspect of the invention is directed to a method of communicating data over a network, comprising: generating, by a first node, a frame addressed to a second node; encoding, by the first node, the generated frame by applying forward error correction (FEC) coding on the generated frame in such manner that blocks or removes a predetermined set of forbidden symbols (FS) from the encoded frame; and transmitting, by the first node, the encoded frame to the second node. A second aspect of the invention is directed to a method for communicating data over a mixing segment of an Ethernet network by using node A and node B communicatively connected to the mixing segment. According to the second aspect, the method comprises generating, by node A, an Ethernet frame E addressed to a node B; applying, by node A, a Reed-Solomon -type encoding to the Ethernet frame E to generate an encoded Ethernet frame E′; transmitting, by node A, the encoded Ethernet frame E′ over the mixing segment; receiving, by node B, from the mixing segment the encoded Ethernet frame E′; and applying, by node B, a Reed-Solomon-type decoding to the Ethernet frame E′ to obtain a forward error correction representative of the original Ethernet frame E. In this second aspect, Reed-Solomon encoding may be applied by generating a list of forbidden symbols FS and, when applying the Reed-Solomon control symbols to the Ethernet frame E, removing or blocking the forbidden symbols FS from the encoded Ethernet frame E′

This application is a Continuation of PCT International Application No. PCT/IB2021/057420, filed on Aug. 11, 2021, which claims priority under 35 U.S.C. 119(e) to U.S. Provisional Application No. 63/064,822, filed on Aug. 12, 2020, all of which are hereby expressly incorporated by reference into the present application.

### BACKGROUND OF THE INVENTION

### Field of the Invention

The present invention relates to a method for communicating data over a mixing segment of an Ethernet network, and more particularly, to a method for communicating data over a 10BASE-T1S Ethernet network segment using nodes communicatively connected to the mixing segment.

### Discussion of the Related Art

IEEE Std 802.3cg-2019 established a new pair of Ethernet physical layer devices (PHYs), one of which, the short-reach 10BASE-T1S, uses 4B/5B mapping over Differential Manchester Encoding (DME) to maintain a data rate of 10 Mb/s at a MAC/PLS interface, while providing in-band signaling between transmitter and receiver(s). However, 10BASE-T1S does not have any error correcting scheme built into it.

### SUMMARY OF THE INVENTION

As a response to emerging building, industrial, and transportation requirements, an object of the present invention is to create a low-complexity, backward compatible Forward Error Correction (FEC) with per-frame configurable guaranteed burst error and erasure correcting capabilities over any 10BASE-T1S Ethernet network segment. Another object of the present invention is to combine a specialized, systematic Reed-Solomon code and a novel three-tier technique to avoid the appearance of certain inadmissible codeword symbols at the output of the encoder, thus enabling error and erasure correction while maintaining backward compatibility with the current version of the standard.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a first aspect of the invention is a method for communicating data over a mixing segment of an Ethernet network, in particular over a 10BASE-T1S Ethernet network segment, by means of node A and node B communicatively connected to the mixing segment. The method comprises: generating, by node A, an Ethernet frame E addressed to a node B, applying, by node A, a Reed-Solomon-type encoding to the Ethernet frame E to generate an encoded Ethernet frame E′, and transmitting, by node A, the encoded Ethernet frame E′ over the mixing segment.

According to an embodiment of the first aspect, receiving, by node B, from the mixing segment the Ethernet frame E′, and applying, by node B, a Reed-Solomon-type decoding to the Ethernet frame E′ to obtain a forward error correction representative of the original Ethernet frame E.

According to an embodiment of the first aspect, applying a Reed-Solomon-type encoding comprises: generating a list of forbidden symbols FS, and when applying Reed-Solomon parity symbols to the Ethernet frame E, removing or blocking the forbidden symbols FS from the encoded Ethernet frame E′. Forbidden symbols FS may comprise the symbols listed in table 2 below.

A second aspect of the invention is an Ethernet bus node, comprising a transceiver circuit, which comprises a media access control MAC and a PHY. The Ethernet node is configured to run the method according to the first aspect.

According to an embodiment, the Ethernet bus node is configured to communicate over a mixing segment, in particular over a 10BASE-T1S Ethernet network segment.

According to an embodiment, the mixing segment comprises a twisted-pair cable, and the transceiver circuit of the Ethernet bus node is configured to be connected to the twisted-pair cable.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. The patent or application file contains at least one drawing executed in color. Copies of this patent or patent application publication with color drawing(s) will be provided by the Office upon request and payment of the necessary fee. In the drawings:

FIG. 1 illustrates the layering of functions in a typical PHY with Autonegotiation (AN), Forward Error Correction (FEC), scrambler, and Reconciliation Sublayer (RS);

FIG. 2 illustrates the IEC 61000-4-4 Electrical Fast Transient (EFT) test setup;

FIG. 3 illustrates the timing of 4B/5B mapping of a PPHY;

FIG. 4 illustrates the PCS_Rx state diagram of a PPHY;

FIG. 5 illustrates a possible encoding process of a {15, 15} coding scheme using a (15, 13) RF FEC over GF (32);

FIG. 6 illustrates the existence of {c, u} and coding scheme candidates for t=1;

FIG. 7 illustrates a layout of a {19, 19} coding scheme in a (19, 17) RS codeword;

FIG. 8 illustrates various simple example linked lists over 12 DS;

FIG. 9 illustrates various complex example linked lists over 12 DS;

FIG. 10 illustrates a relationship between the number of complete DS (horizontal axis) and the number of FTR's required by each (vertical axis);

FIG. 11 illustrates an (optimized) polynomial long division of a {19, 19} coding scheme that produces PS P1 and P2;

FIG. 12 illustrates a correlation between number of complete DS and the quantity of information (in bits) needed to encode all FTRs;

FIG. 13 illustrates a complete encoding in an example {19, 19} coding scheme;

FIG. 14 illustrates a complete decoding in an example {19, 19} coding scheme;

FIG. 15 illustrates the existence of all {c, u} coding scheme candidates for t≥1 (with white numbers in filled-in carets under t=2 representing the values for [symbol] .

### DETAILED DESCRIPTION OF THE INVENTION

In the following detailed description, reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention. Wherever possible, the same reference numbers will be used throughout the drawings to refer to the same or similar parts.

For purposes of this written description, the term “PHY” will be used to refer to an Ethernet physical layer device, while the term “MAC” (an acronym for medium access control) will be used to refer to a link layer device to be connected by the PHY to a physical medium (e.g., optical fiber or copper cable).

### Section 1: Introduction

The Institute of Electrical and Electronics Engineers (IEEE) project 802.3cg (P802.3cg) concluded in 2019 after about 3 years of research and standardization work involving several key individuals working in the automotive, industrial, building automation, process control, in-system networking technology. The project defined two 10 Mb/s baseband Ethernet Physical Layer (PHY) devices, each for use over a single balanced pair of conductors. One PHY, 10BASE-T1L, was for reaching up to 1 km, and the other PHY, 10BASE-T1S, was specified for short reach applications such as automotive or in-system networks. 10BASE-T1S included a mode for shared-media, a.k.a. multidrop, operation. This project marked a return for Ethernet standards not only to 10 Mb/s speeds, but also to shared media communications, allowing more than two nodes to be attached to a single piece of wire. The shared media mode has garnered interest for extending the capabilities of 10BASE-T1S.

Details about IEEE P802.3cg can be found in the following documents, both of which are incorporated herein by reference in their entireties:
G. A. Zimmerman, P. Jones, J. Lewis, P. Beruto, S. Graber, H. Stewart, “IEEE P802.3cg 10 Mb/s Single Pair Ethernet: A guide,” Jan. 16, 2019; and
IEEE Standard for Ethernet, Amendment 6: Physical Layer Specifications and Management Parameters for 10 Mb/s Operation and Associated Power Delivery over a Single Balanced Pair of Conductors, IEEE Std 802.3cg-2019.

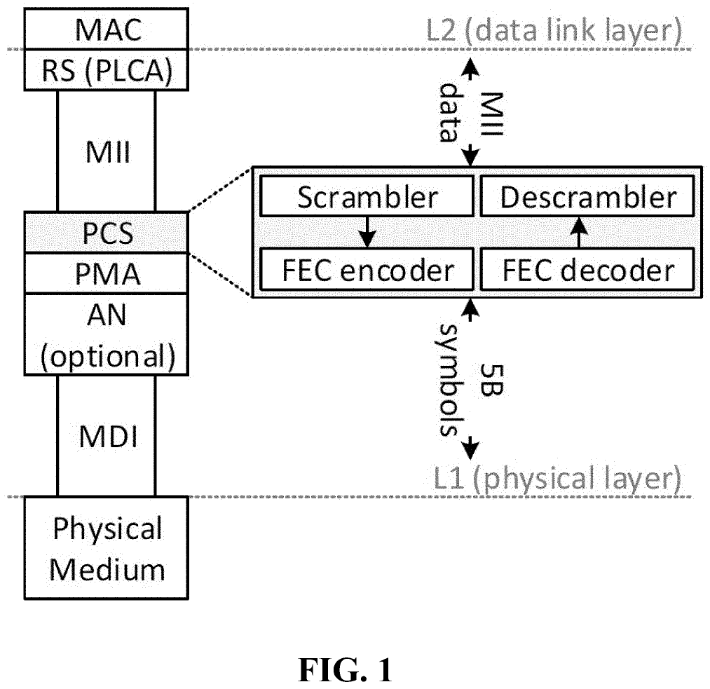

IEEE Std 802.3 (i.e., IEEE Standard for Ethernet, IEEE Std. 802.3-2018) uses certain nomenclature which we will use here as well. The standard refers to the “portion of the Physical Layer that contains the functions for transmission, reception, and—depending on the PHY—collision detection, clock recovery, and skew alignment” as the Physical Medium Attachment (PMA). Above the PMA, further from the medium, resides the Physical Coding Sublayer (PCS), which “contains the functions to encode data bits for transmission via the PMA and to decode the received conditioned signal from the PMA.” An explanation will be provided later of constraints and design on a Forward Error Correction (FEC) approach, which would reside in the PCS, as shown in FIG. 1.

The 10BASE-T1L PHY is a long-reach, strictly point-to-point PHY supporting full-duplex low-power operation. 10BASE-T1L is specified by Clause 146.

The 10BASE-T1S PHY is a 10 Mb/s, short-reach, ultra-low complexity PHY, with an optional multidrop mode of operation. Additionally, a multidrop 10BASE-T1S PHY can provide packet fairness (see Sujan Pandey, Philip Axer, Don Pannell, “PLCA data-rate fairness,” March 2018, which is incorporated herein by reference in its entirety), bounded and calculable channel access delay, and effective throughput of near 10 Mb/s even at network saturation using the Physical Layer Collision Avoidance (PLCA) protocol specified in Clause 148 of IEEE Std 802.3cg-2019 and a Physical Layer Collision Avoidance (PLCA) technique, capable offering bounded channel-access time and a total effective throughput of near 10 Mb/s even at network saturation (see Piergiorgio Beruto, Antonio Orzelli, “Proposal for short-reach multidrop 10M SPE (formerly PLCA),” Sep. 14 2017, the entire contents of which are incorporated herein by reference; and Piergiorgio Beruto, Antonio Orzelli, “802.3cg draft 2.0 PLCA (Clause 148) Overview,” Jul. 9, 2018, the entire contents of which being incorporated herein by reference).

Traditionally, point-to-point Ethernet links, such as 10/100/1000BASE-T, have dealt with feature enhancements by using an Autonegotiation (AN) protocol to signal the capabilities of the PHY at the other end of the link and agree on the highest level of functionality common to the two PHYs. On a point-to-point Ethernet link AN affects only two PHYs making negotiation and single-ended upgrades simple. However, when the PHYs are on a shared media mixing segment, an extension of the AN approach would limit all PHYs on the mixing segment to the capabilities of the least capable node on the mixing segment, making upgrades more difficult. Because impulse noise might be location-dependent in an operational environment, it is possible that only a subset of network nodes might be impacted by noise, creating a situation where some nodes might gain more benefit from upgrading to FEC transmission and reception than others.

An alternative to requiring upgrade of all the nodes on a shared segment would be to provide a method of coexistence so that messages intended for a node capable of decoding the new FEC could be transmitted without spreading errors throughout the network from PHYs incapable of decoding the FEC. While there are many well-known error-correcting codes which might be used (see, e.g., W. Carry Huffman, Fundamentals of Error-Correcting Codes, Cambridge University Press, February 2010), the unique primary challenge in this case is backwards compatibility. Backwards compatibility requires that the encoding is formulated so that any new (FEC-enabled) nodes are able to coexist on the same shared medium as the nodes previously specified in IEEE 802.3cg without knowledge of the FEC. In short, any FEC must fit within the existing line coding scheme and not cause existing 802.3cg nodes to forward erroneous frames to their MACs. Achieving these goals while keeping PHY complexity (measured in gate count) and encoding/decoding latency low are the primary objectives of this paper.

To remain compatible with the present 802.3cg 10BASE-T1S PHY with PLCA (sometimes referred to hereinafter as a “PPHY”), while also implementing an FEC with known burst and erasure correcting capabilities, a new type of PHY (sometimes referred to hereinafter as a “NPHY”) must meet a specific set of conditions described in detail later in our paper. These conditions can be met by the careful selection and combined application of a set of techniques. These techniques take advantage of the inherent and unused redundancy present in the PPHY's 4B/5B mapping while systematically avoiding certain inadmissible 5B symbols, subsequently referred to as Forbidden Symbols (FS), in order to control how the new frames are interpreted by the receiver in a PPHY. As to forbidden symbols (FS), a discussion can be found in Declercq, M. Fossorier, E. Biglieri, Channel Coding—Theory, Algorithms, and Applications, Academic Press Library in Mobile and Wireless Communications, 2014, which is incorporated herein by reference in its entirety.

It should be noted that, while the solution being presented herein is described in regard to the specific coding in 10BASE-T1S, the method described in this specification may be used to enhance any similar system where code groups are used to encode control information along with transmitted data in a network, allowing both enhanced and legacy nodes to be supported.

### 1.1 Outline of the Following Disclosure

Section 2 of this specification introduces the inner workings of the 10BASET1S PHY, including the necessary conditions to remain backward-compatible with it, and what constitutes an FS at different parts of the FEC codeword. Section 3 explains how the unused redundancy present in PPHY's 4B/5B mapping may be used in exemplary embodiments to implement a backward-compatible FEC for burst errors and erasures, including restrictions on the rate, field size and code parameters, and it shows that candidate codes exist. This is followed by Section 4, which describes novel techniques and their unique combination, according to exemplary embodiments of the invention, as well as various constraints related to avoiding the appearance of FS in the codeword. Section 5 describes techniques to implement error-resilient framing to achieve arbitrary burst error correcting capabilities, according to exemplary embodiments. Section 6 analyzes the error burst error correcting capabilities and the encoding delay of exemplary embodiments, and the method through which its correctness was verified. The last section offers conclusions (Section 7).

Additionally, several of the results mentioned in Section 4 are explained through the {19, 19} coding scheme and an example based on that. For reasons discussed below, the {19, 19} coding scheme may be the simplest coding scheme to exist.

### 1.2 Terms and Definitions

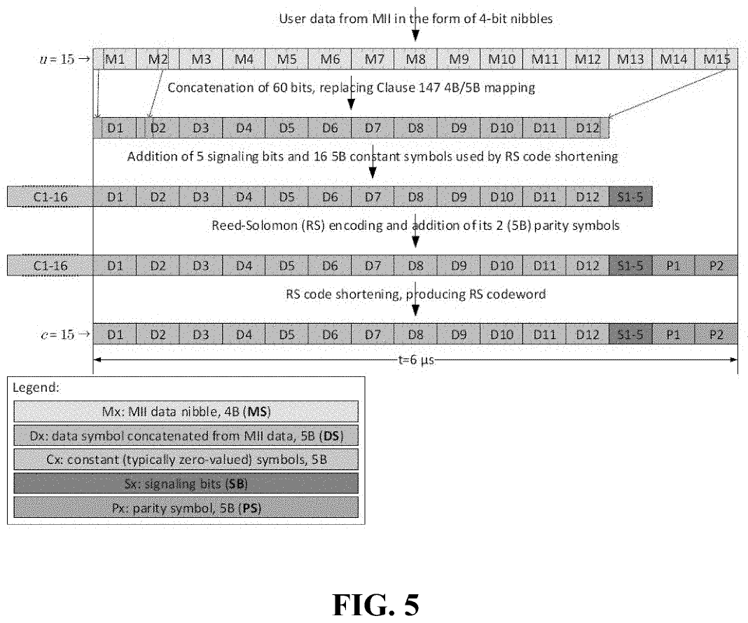

The following table defines certain terms that will be referred to in the following sections:

| Term | Definition | Reference |
|---|---|---|
| NPHY | A new 10BASE-T1S PHY according to | Section 1 |
| | exemplary embodiments | |
| PCS | Physical Coding Sublayer | |
| PLCA | Physical Layer Collision Avoidance | |
| | (specified by Clause 148 of | |
| | IEEE Std 802.3cg-2019) | |
| PMA | Physical Medium Attachment | |
| FS | Forbidden (inadmissible) 5B symbol | Section 1, |
| | | Table 1 |
| DME | Differential Manchester Encoding | Section 2 |
| PPHY | The present 10BASE-T1S PHY specified | |
| | by Clause 147 of IEEE Std 802.3cg-2019] | |
| DS | 5B data symbol, or sequence thereof, | Section 3.22, |
| | carrying concatenated user data | FIG. 5 |
| MS | 4B user data symbol (a.k.a. nibble) or | |
| | sequence of these, conveyed by MII | |
| PS | Parity symbol, or sequence of these, of the RS codeword | |
| SB | Signaling bit, or sequence of these, in | |
| | the RS codeword for FS avoidance | |
| FTR | FS transcoding recipe | Section 4.2 |
| LSB | Least Significant Bit | Section 4 |

### 1.3 Channel Model

For purposes of this specification, and following industrial and automotive requirements, it is assumed that exemplary embodiments of the present invention are used in connection with a binary burst error channel with optional erasure detection, where the erasure detection may rely on side-channel information coming from a receiver that is capable of signaling erasure.

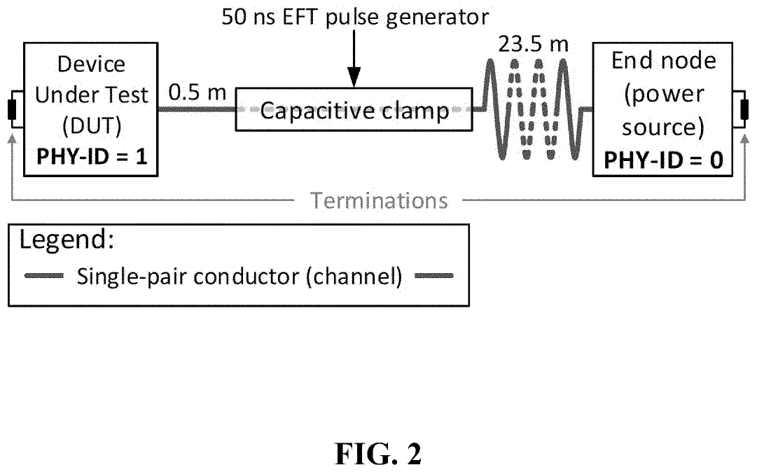

The burst error environment assumed here is rooted in IEC 61000-4-4 Electrical Fast Transient (EFT) test common in industrial systems (as described in IEC 61000-4-4:2012, Electromagnetic compatibility (EMC)—Part 4-4: Testing and measurement techniques—Electrical fast transient/burst immunity test, which is incorporated herein by reference in its entirety). This test exposes the communications link to a sequence of 50 ns disturbance pulses in the test setup shown by FIG. 2. This arrangement is analogous to the schematic diagram of Shannon's general communication system, as disclosed in C. E. Shannon, “A Mathematical Theory of Communication,” The Bell System Technical Journal, volume 27, pp. 379-423, 623-656, July and October 1948, which is incorporated herein by reference in its entirety. Given that the line-encoded bit time in 10BASE-T1S is 80 ns, 50 ns stimuli would be expected to influence at most 2 bits per pulse. In practice, however, due to the common mode impedance the EFT pulse coupled to the differential pair spreads in time and can cause errors on the channel for up to 450 ns per pulse. This has been shown by analogue simulations (see Cameron Jones, “Noise Immunity for Single Pair Cabling and Applicability to Industrial Applications,” Jan. 27, 2020, which is incorporated herein by reference in its entirety), and results in up to 6 bits of burst errors.

It is believed that these values represent a test setup that is specific to industrial environment, and thus exemplary embodiments of the present invention are aimed at leaving burst error correcting capabilities as a free variable, possibly configured for each frame separately as required by the specific system and the actual, assumed, or predicted status of the segment.

### Section 2: The Present 10BASE-T1S PHY (PPHY)

### 2.1: The PPHY Frame

An Ethernet frame is encapsulated into a 10BASE-T1S frame, which starts off with a fixed sequence of 5B symbols with carefully crafted auto- and cross-correlation properties (see Gergely Huszak, Hiroyoshi Morita, “On the 10BASE-T1S preamble for multidrop,” presented at the GIIS 2019, Paris, France, Dec. 18-20, 2019, which is incorporated herein by reference in its entirety), followed by five 5B symbols (25 bits) encoding a per-frame lock sequence for the 17-bit scrambler of the PPHY. The lock sequence is followed by the actual data received from the MAC/PLS, and the frame is terminated by the appropriate End Sequence Delimiters (ESD), indicating success or failure of the frame transmission attempt.

### 2.2: FEC in the Abstract Layering

The PPHY incorporates a multiplicative scrambler (see Byeong G. Lee, Seok C. Kim, Scrambling Techniques for Digital Transmission (Telecommunication Networks and Computer Systems), Springer, May 16, 2000, which is incorporated herein by reference in its entirety), to eliminate unacceptable electromagnetic emissions (see Subclause “147.5.4.4.2 PSD mask” in IEEE Std 802.3cg-2019) from so-called “killer packets” containing periodic data patterns. The multiplicative scrambler operates only on payload data and not on 4B/5B encoded control symbols. Because multiplicative scramblers propagate errors in the received data sequence, it is desirable to place the FEC to operate on the scrambled data sequence to minimize errors into the descrambler at the receiver as shown in FIG. 1.

### 2.3: 4B/5B Encoding

Clause 147 defines a specific 4B/5B mapping as follows:
1. 4-bit user data nibbles (4B symbols) at the Media-Independent Interface (MII) are mapped to 5-bit (5B) symbols of the PMA to be transmitted on the wire using Differential Manchester Encoding (DME);
2. 8 of the remaining 16 5B symbols are used to control functions of the PCS and the PLCA;
3. The remaining 8 5B symbols are unassigned and unused.

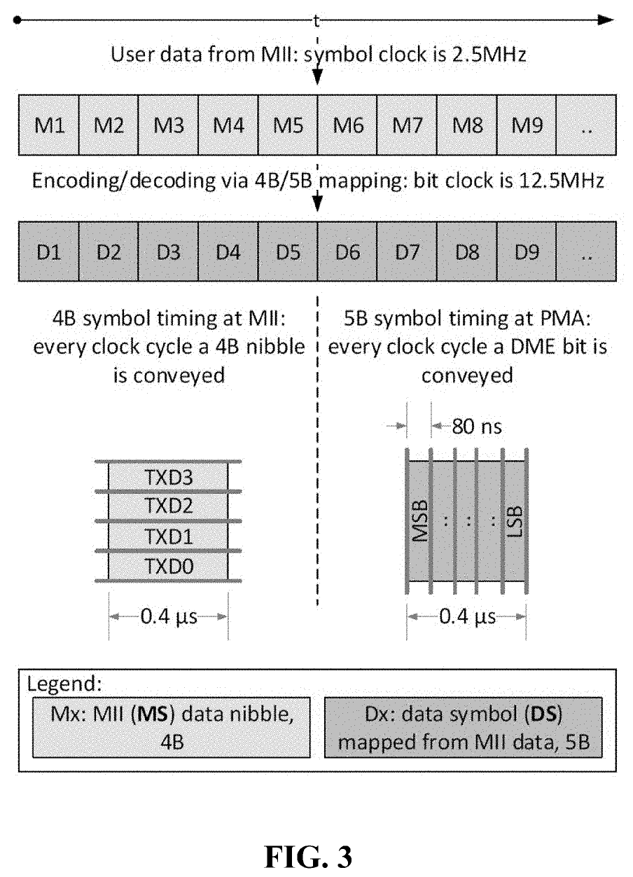

At the MII, 4-bit nibbles are clocked at a rate of 2.5 Mb/s, while the PMA is handling DME bits at 12.5 Mb/s, the details of which are shown by FIG. 3. As visible in the figure, a DME encoded 5B symbol is transmitted by the PMA in the same amount of time (nominally 400 ns) as a 4B nibble is received via the MII.

### 2.4: Backward Compatibility

In order for 10BASE-T1S NPHYs and PPHYs to be backwards compatible and coexist on the same network segment, the following requirements must be met:
1. Any 10BASE-T1S PHY must be able to receive the bit stream predictably. This means that the PMA of both the PPHY and NPHY must transmit and receive DME bits at a rate of 12.5 Mb/s (i.e., 2.5 MHz for 5B symbols);
2. PPHY's PCS receive (PCS_RX) function must manifest predictable behavior when receiving a coded sequence from an NPHY;
3. Transmission of NPHY should not produce control sequences that would disrupt the PLCA cycle of PPHY;
4. The data rate at the MAC/PLS interface of 10 Mb/s must be maintained, preferably without the need for buffers within the PHY. This is desirable, because such buffers would have to scale with the size of the largest Ethernet frame transmitted.

Achieving the 1st criterion constrains the NPHY to DME transmission of 5B symbols at a 12.5 Mb/s line rate. This, together with the 4th criterion of a 10 Mb/s rate at the MAC/PLS interface, implies that whatever encoding is used must have a rate of no less than 4/5=0.8.

### 2.4.1: Backward Compatibility with PPHY's PCS

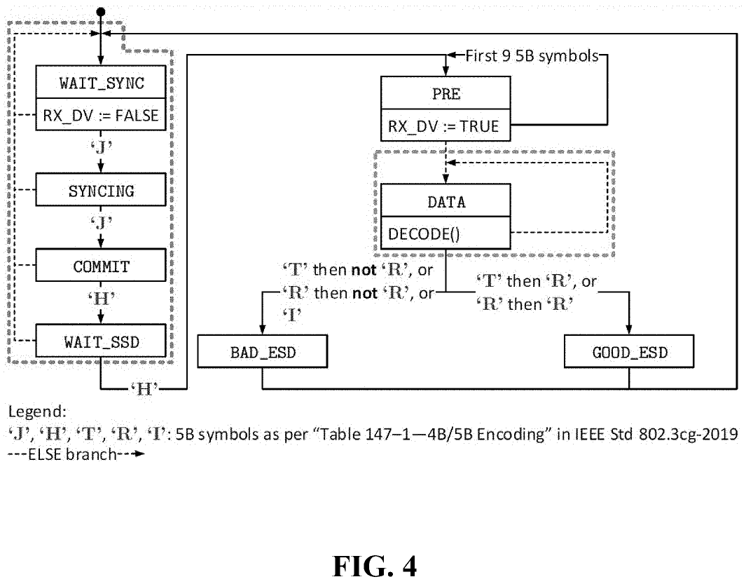

Detailed analysis and simulation (shown in Section 6.2.1 below) of the PPHY's PCS_RX state diagram, the essence of which is depicted in FIG. 4, showed that to prevent a PPHY from going through an unpredictable sequence of states in all cases when receiving a frame from NPHY, its PCS RX has to be locked into the controllable iteration. The iteration is highlighted by the brown dotted area in FIG. 4, and is implemented by the DATA state itself. The details of the criteria necessary for this are summarized by Table 2, from which it is apparent that receiving certain 5B symbols (‘T’, ‘R’, and ‘I’ represented by the binary values shown by Table 1) cause the PCS_RX to exit DATA state.

TABLE 1
Forbidden Symbols (FS) for the NPHY

| In Clause 147 (4B/5B) | | | |
|---|---|---|---|
| Symbol | Special | Binary | Exponential and |
| name | function | value | polynomial forms |
| ‘T’ | BSD, | 01101 | α⁸ = α³ + α² + 1 |
| | HB | | |
| ‘R’ | ESDOK, | 00111 | α¹¹ = α² + α + 1 |
| | ESDBRS | | |
| ‘T’ | SILENCE | 11111 | α¹⁵ = α⁴ + α³ + α² + α + 1 |

Not in Clause 147

| | | |
|---|---|---|
| ‘X’ | FECESD | (as applicable) |

Note:
in Table 1, the exponential forms are shown for the example case where the field generator polynomial p(x) = x⁵ + x² + 1 over GF (2⁵), where α is the primitive element (root) of the field

TABLE 2
Exit Scenarios from state DATA of PCS_RX of the PPHY

| | | | ELSE | |
|---|---|---|---|---|
| RXₙ₋₃ = ‘I’ | RXₙ₋₃ = ‘T’ | RXₙ₋₃ = ‘R’ | RXₙ₋₁ = ‘R’ | RXₙ₋₁ ≠ ‘R’ |

| RXₙ₋₂ = ‘T’ | BAD | — | | BAD |
|---|---|---|---|---|
| RXₙ₋₂ = ‘R’ | | GOOD | — | |

| | |
|---|---|
| ELSE | — |

Legend:
GOOD: The transition DATA→GOOD_ESD
BAD: The transition DATA→BAD_ESD
—: No transition from state DATA

It is worth noting that another cyclic sequence of states exists in the PCS_RX that may also allow locking the receiver. This sequence, the WAIT_SYNC→(SYNCING→(COMMIT→(WAIT_SSD→)))WAIT_SYNC→ . . . , is highlighted by the blue dotted area in FIG. 4, and is there to decode the preamble of the packet. However, this cycle is not useful because it interferes with the operation of the PLCA by de-asserting RX_DV (see next subsection for more details).

As explained in Section 2.1 a PPHY frame is terminated by ESD. In a noisy environment special care must be taken to maintain error resilience not only for the payload, but also for this component of the packet. To be able to signal end of frame—and possibly additional side-information—with error resilience that is at least as good as that of the payload, an additional (4th) 5B symbol is reserved from the set of those 5B symbols without a defined mapping in the PPHY. In this paper we will refer to this FECESD FS as ‘X’, forming the 4th element of the FS set we build on. For the reasons explained in Section 5.1, ‘X’ should be treated as an FS only among user data symbols (DS) of the codeword.

In short, an NPHY can remain compatible with the PPHY's PCS by using an encoding which excludes a specific set of 5B symbols from its alphabet while in the DATA. This locks the PPHY receiver's PCS_RX in the DATA state and prevents the receiver form propagating the data to the MAC.

In addition to this, the received frame should be specifically marked as bad by the PPHY. This is achieved by ensuring a PPHY transitions from DATA to WAIT_SYNC through BAD_ESD, as that asserts the RX_ERR MII signal, and therefore rules out the possibility that the data may be erroneously received by the PPHY's MAC. This transition through BAD_ESD can be ensured by terminating the frame with a ‘T’ followed by a ‘K’ (where ‘K’ has the special function ESDERR and binary values 10001 assigned to by Table “147-1—4B/5B Encoding” in IEEE Std 802.3cg-2019).

### 2.4.2 Backward Compatibility with PLCA

To summarize the criteria for an NPHY's FEC-encoded transmission to be backward compatible with a PPHY, it has to use the no more redundancy than is present in PPHY's 4B/5B mapping and must avoid the appearance of FSs in the codewords. Assuming that |FS|=4, where the operator |S| denotes the cardinality of set S, the quantity of this unused information is log₂(32−4)−4≈0.8 bit per 5B symbol.

### Section 3: The FEC of Choice

### 3.1 Considerations for Choosing the FEC Scheme

The sensor and IoT applications desired for 10BASE-T1S require low-complexity implementations, and hence research has been driven towards known low-complexity coding techniques. Research within 802.3 has shown that linear block codes have considerable history in Ethernet. Therefore, a focus has been on ways to use coding structures familiar in industry that have existing, proven implementations.

A linear block code is characterized by an (n, k, dₘᵢₙ₎ triplet, where n denotes the number of codeword symbols, k stands for that of message symbols, and dₘᵢₙ represents the minimum distance of the code (see L. R. Vermani, Elements of Algebraic Coding Theory, Chapman Hall/CRC Mathematics Series, Jan. 1, 1996, which is incorporated herein by reference in its entirety).

As shown later in Section 3.2.3, short block-length is not only preferred to minimize encoding delay at the relatively slow line rate of 10 Mb/s, but is required by existence constraints for the coding scheme.

In order to enable the FS to be escaped before encoding, as described under Section 4, and to take advantage of code shortening, our work further focused on systematic codes.

Maximum Distance Separable (MDS) codes are linear block codes which guarantee that dₘᵢₙ=n−k+1 (see Ron Roth, Introduction to Coding Theory, Cambridge University Press, Feb. 23, 2006, which is incorporated herein by reference in its entirety). In other words MDS codes are (n, k, n−k+1), often referred to as (n, k), and t=└(n−k)/2┘, where t denotes the maximum number of correctable errors. As described in Section 2.4.3 the inherent and reusable redundancy present in the 4B/5B mapping used by the PPHY is relatively small, and therefore MDS codes are the preferred choice for establishing error resilience with low complexity.

Research within IEEE 802.3, and that involving vendors of FEC IP blocks, has shown that while there is a multitude of proven FEC implementations using linear codes and the industry has ample experience with them, these all work over binary (extended) fields. Practical implementations of FEC schemes using ternary or larger base fields are harder to find, and hence a focus has been placed on codes from binary (extended) fields.

However, it is known that the only MDS binary codes that exist are the trivial (n, n) codes, and the Single Parity Check (n, n−1). Therefore, research has focused on Reed-Solomon (RS) codes over extended binary fields.

### 3.2 Reed-Solomon (RS) Error Correcting Codes

A discussion of Reed-Solomon (RS) error correcting codes can be found in the following references, all of which are incorporated herein by reference in their entireties:
I. S. Reed, G. Solomon, “Polynomial Codes over Certain Finite Fields,” Journal of the Society for Industrial and Applied Mathematics, volume 8, issue 2, pp. 300-304, 1960;
R. C. Bose, D. K. R Chaudhuri, “On a class of error correcting binary group codes,” Information and Control, volume 3, issue 1, pp. 68-79, March 1960;
Alexis Hocquenghem, “Codes correcteurs d'erreurs,” Chiffres, volume 2, 1952;
A. J. Han Vinck, Coding Concepts and Reed-Solomon Codes, Inst. For Experimental Mathematics, Essen, Germany; and
C. K. P. Clarke, “Reed-Solomon error correction,” Research and Development BBC, July 2002.

RS codes are a group of linear cyclic MDS codes over a finite field (GF) that can be used in systematic mode. They belong to the family of Bose-Chaudhuri-Hocquenghem (BCH) codes, and satisfy all the criteria listed in Section 3.1.

Moreover RS codeword shortening allows fine-grained adjustment of code performance. Additionally, encoders and decoders for known code parameters can be considerably optimized, and a multitude of efficient and proven silicon implementations exist for extended fields where the base prime is 2. For these reasons RS codes are a perfect fit for the problem at hand, subject to the constraint that a method can be found to avoid FS.

### 3.2.1 Field Size vs. Interleaving, and RS Code Parameters

A key attribute of an RS code is the finite field (GF) over which it is defined. FEC IP blocks are commonly optimized to use pre-calculated lookup tables to speed up arithmetic operations between field elements (scalars) of, and polynomials over these. As the sizes of these lookup tables scale quadratically with the cardinality of the field, it is essential to keep the field size small to manage complexity. The reduction in burst-error correction capability may be offset by the well-known technique of interleaving. A lower bound on the field size is present if interleaving is used: if the number of bits necessary to represent all field elements is not divisible by log₂(32)=5, interleaving does not achieve the increase in these capabilities. Therefore the smallest extended field for our FEC is GF(2⁵), also referred to as GF(32).

Let [α, β] denote the closed integer interval with the minimum and maximum values of α and β (respectively). It is known that over GF(32) an (n, k) RS code exists, such that n≤32−1=31, and code shortening makes it possible to choose any integer in [1, n−dₘᵢₙ+1] as k. This is because the unused input symbols are replaced by a pre-agreed constant symbol pattern, and these can be omitted during the transmission of the codeword due to the fact that the code is systematic. In this paper we will refer to this RS code through its parameters (n, n−2t).

### 3.2.2 Encoding Process

To summarize previous subsections, we can state that an (n, n−2t) RS code over GF(32) is applicable to the problem at hand. An encoding process would first receive 4B user data nibbles from the MII, concatenate them, apply the necessary technique to avoid the appearance of FS anywhere in the codeword, and finally feed the resulting block to the RS encoder. The encoded block is passed to the PMA for DME-encoded serial transmission over the wire.

Before going further with our observations, let us introduce two new parameters as follows:
c denotes the total number of 5B symbols in the RS codeword, including the parity check symbols, thus c=n=k+2t;
u represents the total number of 4B user data symbols, thus u≤└5k/4┘.

There are 3 things worth noting here:
1. This process created an FEC codeword consisting of some 5B symbols concatenated from u 4B user data symbols (referred to as DS), some signaling bits (SB), and 2t parity symbols (PS);
2. The FEC codeword created has the exact same length in time domain as the user data, which consisted of 4B symbols (denoted as MS); and
3. The signaling bits, SB, are free bits that may be used to avoid the appearance FS anywhere in the codeword, the details of which is described under Section 4.

From hereon we will refer to such a construct as a (c, u) coding scheme. A summary of all the parameters and the encoding process described above is depicted in FIG. 5 for the case c=15 and u=15.

FIG. 5 also shows the additional step necessary for code shortening, during which transmitter and receiver use a previously agreed constant pattern at |GF|−1−c 5B symbol positions, referred to as Cx. In the example shown by FIG. 5 this is 32−1−15=16, and those 16 5B symbols are referred to as C1-C16. Note that implementations may omit the step of filling these locations without penalty if constant symbols represented by all zero bits are used. Also, in the later part of this specification, these steps will not be shown.

### 3.2.3 Existence of Code Parameters

Section 3.2.2 showed an encoding process that relies on an example selection of values for the coding parameters c and u, however it is apparent that these are not free variables. In this subsection, the three basic criteria or conditions that should be met for a coding scheme candidate to exist are explained below:
1. The rate r of the code, which is defined as r=4u/5c, should satisfy r≥0.8 to meet the backward-compatibility criterion described in Section 2.4, thus:

u≥c (1)
2. The number of bits represented by MS must fit into the DS that are present in the codeword, thus if t denotes the number of correctable 5B symbols errors, and [symbol] denotes the number of bits embodying SB, then:

5(c−2t)≥4u+ [symbol] (2)
3. The number of SB shall be sufficient to be able to point to the first FS in the linked list, as described under Section 4.3, thus:

[symbol]

≥log₂(└4u/5┘+1) (3)

From (2) it follows that [symbol] ≤5(c−2t)−4u and, if [symbol] is maximized, then [symbol] =5(c−2t)−4u.

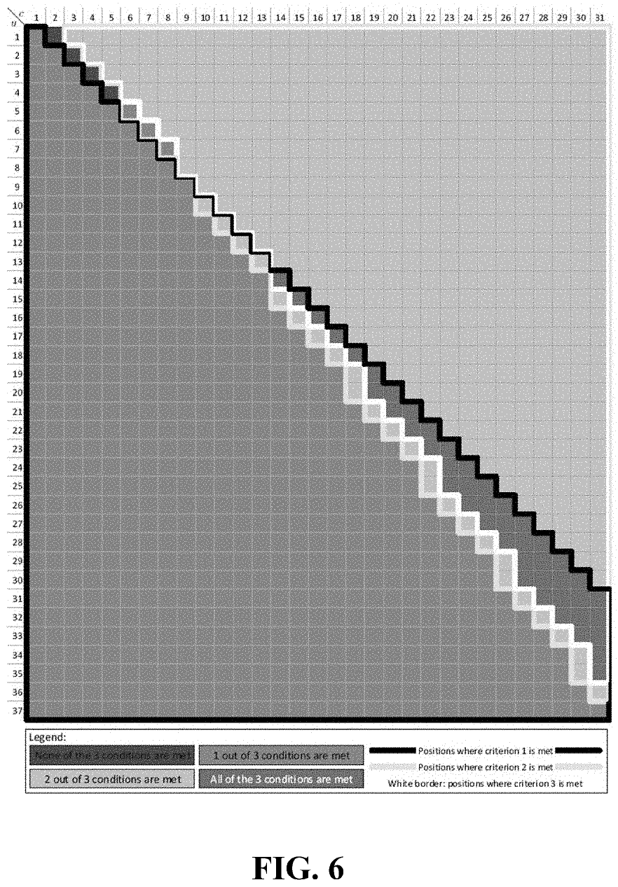

FIG. 6 shows the relationship between all possible values of c and u, and how each of necessary conditions gets satisfied throughout the parameter space, under the assumption that t=1 using the following color scheme:
Black border (encircling the lower triangle and the diagonal it forms) shows positions where (1) is satisfied;
Yellow border (surrounding approximately the upper triangle) shows the positions where (2) is met; and
White border (surrounding a slightly different part of the upper triangle) shows positions where (3) is satisfied.

For a discussion on the cases when t>1, see Section 5.4.

### Section 4: Avoiding Forbidden Symbols (FS)

Section 3 described a set of basic existence criteria and construction techniques that allow creating different {c, u} coding schemes that meet the backward-compatibility requirements described in Section 2.4 with the exception of avoiding the FS. These are only referred to as candidates, since they are not yet complete solutions. In this section, a solution for avoiding the FS is discussed.

Referring to FIG. 5, there are three separate parts of a codeword where FS avoidance for the 5B domain has to be implemented. Each of these are addressed separately by the subsections herein, as follows:
1. FS among the DS: the concatenated 4B user data nibbles received from the MII (MS);
2. FS among the SB: the [symbol] signaling bits that became available as a result of the DS concatenation process described under Section 3.2;
3. FS among the PS: parity symbols (PS) created by the RS encoder through polynomial division.

This specification discloses a unique combination of three novel techniques, each handling one of the three areas, as described by the following subsections.

### 4.1 Layout of the RS Codeword

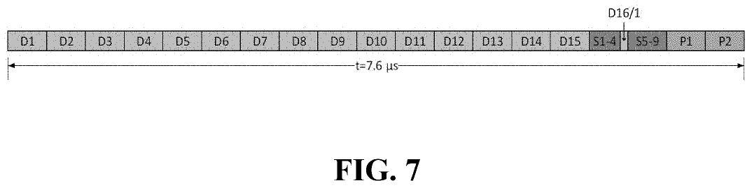

An implementation may choose an arbitrary ordering of DS, SB, and PS. However, the arrangement shown by FIG. 7 will be subsequently used, as it maintains the “LSB first” bit order defined by Clause 147, it also allows pre-coding, and it is compatible with the future extensions proposed in Section 8.

### 4.2 FS Among the DS

The 5B symbols comprising the user data are formed by the concatenation of the unconstrained (free) user input data from the MAC, as shown by FIG. 5. Therefore no general assumption can be made with regards to their values. In this subsection, only DS that are completely made up by MS is being discussed. The mechanisms for MS and SB appearing in a mixed manner are described in Section 4.3.

Because the encoding of the location of the FS must meet the rate requirement, something more efficient than a simple bitmap encoding is needed. Thus, the combined application of the following two methods are proposed to eliminate FS among the DS:
1. A linked list that walks through all the FS present in a forward-only manner while transcoding each FS to an admissible 5B symbol; and
2. A special constellation-ID that allows forming the linked list in those cases when the distance between any two neighboring FS is too large to be directly represented.

A naïve approach to form the linked list would be as follows:
1. Encode in the SB the index of the first FS among the DS, or encode End of List (EoL) if the DS contain no FS;
2. Transcode the FS pointed to by the SB to an admissible 5B symbol value. The transcoding encodes the value of the FS that was replaced (subsequently referred to as fs) and the distance to the next FS in the array of DS (or EoL) (subsequently referred to as δ);
3. This process is repeated until no FS appears among the DS.

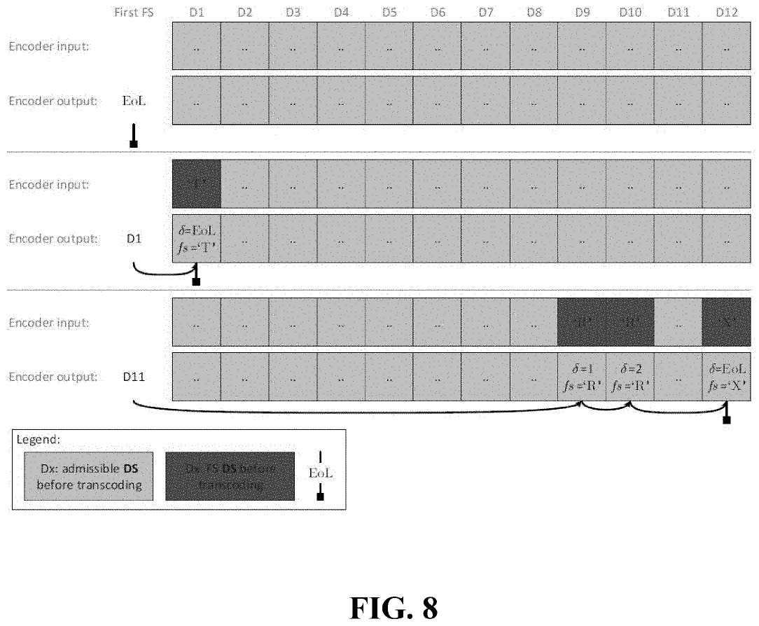

Because all FS are transcoded by the linked list, and all the transcoded fs-δ pairs must be represented only by admissible symbols, no FS appear in the output of this iterative process. FIG. 8 shows some simple examples of how this works under a {15, 15]} coding scheme.

However, this naïve approach is not yet complete. The following observations are made:
1. An unconstrained 5B symbol can represent 2⁵=32 values, which must encode both δ and fs at the same time;
2. There are four FS that have to be considered among DS, decreasing the number of admissible 5B symbol values, which may be used to encode δ, from 32 to 28; and
3. δ has to also be able to encode a value representing EoL.

From these observations it follows that the naive method does not allow δ to be larger than δₘₐₓ=└(32−4)/4┘−1=6. For example if D5 and D12 were FS, the δ part of the 5B symbol value transcoding D5 would be unable to represent the distance of δ=7 between these.

This problem is resolved by the application of the special constellation-ID mentioned above, which carries additional information with respect to the position of all FS before transcoding is carried out. The special constellation-ID indicates either:
None of the distances between any two neighboring FS is larger than δₘₐₓ;
or
There exists one or more neighboring FS, the raw distance (δ_{effective}) between which is larger than δₘₐₓ. For these, we do the following:
   a. Let δ for those be δ=(δ_{effective} mode (δₘₐₓ+1);
   b. Remember both the sequence number and └δeffective/(δmax+1)┘ for those.

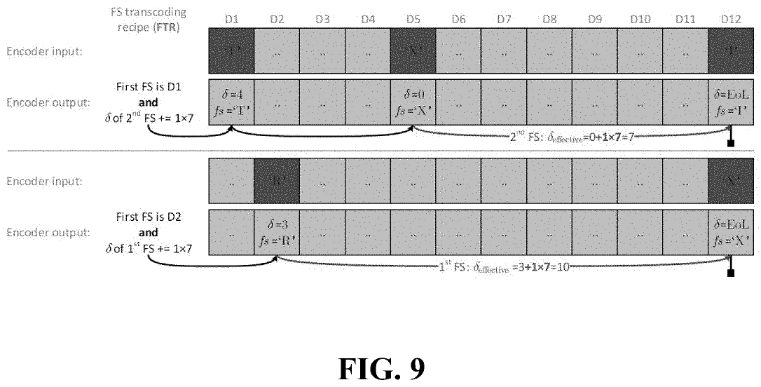

Now, if SB is made to encode the index of the first FS among the DS as well as this special constellation-ID, this method provides a complete solution capable of eliminating all FS among the DS, irrespective of their actual values and locations. In the later part of our paper, we refer to this construct encoded by the SB as an FS Transcoding Recipe (FTR). FIG. 9 shows how FTRs work in some example cases under a {15, 15 } coding scheme.

### 4.3 FS Among the SB

This subsection will discuss how many signaling bits (referred to as SB) are needed to represent all necessary FTRs, while also making sure no new FS are created by the SB during the process.

As explained, SB are [symbol] bits in the codeword, from among which ( [symbol] mod 5) bits form a mixed DS, in which data form the MS and SB coexist, while the remaining └ [symbol] /5┘ 5B symbols are formed by purely SB, as shown by FIG. 7.

In Table 3, it is shown show how many signaling values can be encoded by a 5B symbol with any SB in it. Table 3 also explains what these values are rooted in. From this, for example, it is visible, that a {19, 19} coding scheme, where [symbol] =4+5=9, can encode 13×29=377 FTRs, so that 9 SB (bits) can carry log₂(377)≈8.6 bits of information, while avoiding the appearance of FS among the 5B symbols.

TABLE 3
Relationship between Number of SB in a 5B Symbol and the
Number of Signaling Values that can be Encoded

| Number of | | |
|---|---|---|
| SB in the | signaling | |
| 5B symbol | values | A possible method of optimal construction |
| 1 | 1 | LSB or the central bit must be picked and |
| | | it needs to be 0 to avoid FS: 2¹ − 1 = 1 |
| 2 | 3 | Assign LSB and the central bit, and |
| | | avoid using 1-1: 2² − 1 = 3 |
| 3 | 6 | Same as above, then pick any |
| | | 3^{rd} bit: 2(2² − 1) = 6 |
| 4 | 13 | Pick any 4 bits and avoid the 3 patterns |
| | | FS have their: 2⁴ − 3 = 13 |
| 5 | 29 | Simply avoid using tire 3 FS: 2⁵ − 3 = 29 |

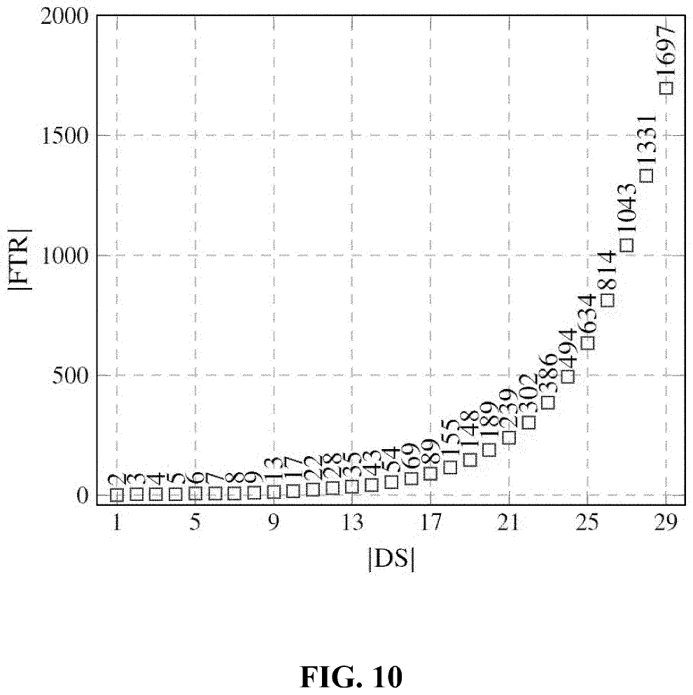

As discussed in Section 4.2, one of the main roles of SB is to encode the FTR required by the coding scheme to avoid FS among the DS. It is obvious however that the number of FTRs needed by the scheme to operate scales with the number of complete DS in it. This relationship is depicted in FIG. 10, the values in which were determined by an exhaustive search. It can be seen, for example, that a {19, 19} coding scheme with 15 complete DS requires 54 FTRs. It is possible that this graph can also be expressed by a closed, recursive, combinatorial formula.

Note that some of the information available in the SB will have to be used to avoid FS appearing among the PS. This role is assigned to the terminal 5B symbol that comprises of SB. In short, non-terminal 5B symbol encoding SB represent only the FTR, while the terminal one supports this, and contributes to avoiding FS appearing among the PS, the details of which is explained in Section 4.4.

### 4.4 FS Among the PS

These 2t 5B symbols are the direct product of the RS encoding of the data bits. Because the data bits are unconstrained and the RS code is MDS, there is no mapping that would avoid the appearance of FS among the PS in all cases. As a result, some additional—yet unused—free bits in the encoder's input must be reserved to influence its output.

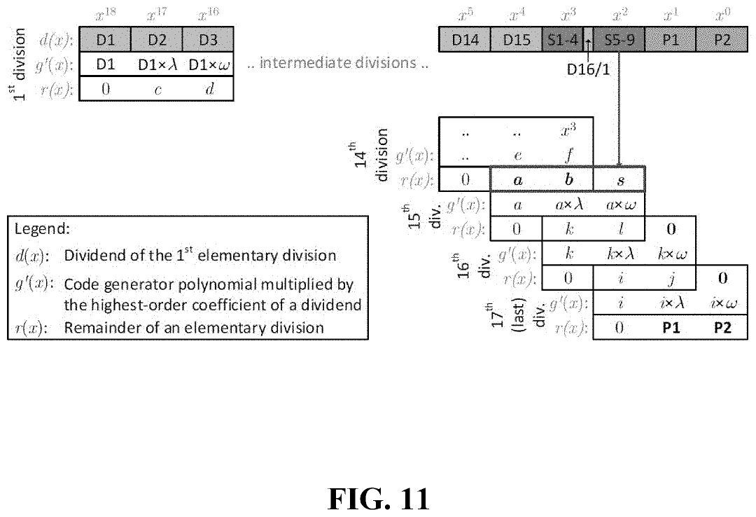

FIG. 11 shows how PS are produced according to known techniques for RS encoding by the iterative process of polynomial long division. It can be noted that for a given code generator polynomial g(x)=x²+λx+ω, the PS are fully determined by three components n−k before the last subdivision (highlighted by the thick red caret), namely:
a and b: the cumulative remainders of all the previous sub-divisions;
s: the last 5 bits of SB, in this case S5-9.

This allows the normal RS encoding process to be modified so that when a and b become available during the execution of the polynomial division, s would be selected from the set of admissible 5B symbol values, so that neither P1 nor P2 would end up being FS. The direct application of this method uses the space in s efficiently, but it requires a large lookup table that selects s based on exact values of both a and b. While this process may be implementable, it may not be feasible for low-complexity systems. This lookup considerably simpler can be made considerably simpler by relying on the following two observations:
All three FS to be avoided among the PS (i.e., ‘T’, ‘R’, and ‘I’ as will be explained in Section 5.1) are identical in their LSB and the central bits, as shown by Table 1; and
Galois field elements are added by modulo-2 addition of their coefficients, which in binary form means bit-by-bit Exclusive OR (XOR) of the two scalars.

Given these observations, FIG. 11 shows that the two SB are a result of the following set of elementary equations over GF(32), where P1, P2, a, b, i, j, k, l, s, λ, ω∈GF(32):

P1=j+iλ

P2=iω

i=l+kλ

j=kω

k=b+aλ

l=s+aω (4)

The straightforward simplification of (4) leads to the following results:

$$P 1 = {\overbrace{a {λ}^{3} + b ( {λ}^{2} + ω ) + s λ}}^{P {1}_{left}} \qquad ( 5 )$$

$$P 2 = {\overbrace{a ( {λ}^{2} ω + {ω}^{2} ) + b λω + s ω}}^{P {2}_{left}} \qquad ( 6 )$$

What is worth noting here is that P1 is fully determined by sλ, and the same holds for P2's relationship with sω. Therefore, to avoid FS among the PAS, the {c, u} coding scheme may proceed as follows:
1. Choose any bit location in the 5B symbol, where all FS have matching values: from hereon we will use LSB, as all three FS have the value 1 at that position;
2. Given

[symbol]

=GF(32)∛{‘T’,‘R’,‘I’}, and ν∈{0,1},
the following two parametric partitionings of the admissible 5B symbol vales are defined, where the function LSB of (n) returns the LSB of n, as follows:

[symbol]

₁(ν)={x∈ [symbol] |LSB_of(xλ)=ν} (7)

[symbol]

₂(ν)={x∈ [symbol] |LSB_of(xω)=ν} (8)
3. During the polynomial division shown by FIG. 11, when a and b become available, calculate P1_{left} and P2_{left}, as per (5) and (6), respectively;
4. Finally, pick a single value for s such that:

s∈ [symbol] ₁(LSB_of(P1_{left}))∩ [symbol] ₂(LSB_of(P2_{left})). (9)

As this method guarantees that both LSB_of (P1_{left}+sλ) and LSB_of (P2_{left}+sω) will always be 0, it follows that neither P1, nor P2 may turn out to be any of the three applicable FS.

It is worth mentioning, however, that the cardinalities of the four sets (| [symbol] ₁(0)|, | [symbol] ₁(1)|, | [symbol] ₂(0)|, and | [symbol] ₂(1)|) depend on the actual values for λ and ω. The cardinalities of these sets may each be anywhere in the interval [5, 7], depending on where the three FS fall in these four sets for the given A and co. As per FIG. 11, it is the terminal 5B symbol that comprises of SB that needs not only to contribute to encoding the FTR, but also implements the avoidance of FS in the PS. Because of this, the number of values available to encode FTR by this symbol is in the same interval, thus it is at most 7.

### 4.5 Information-Theoretic Observations

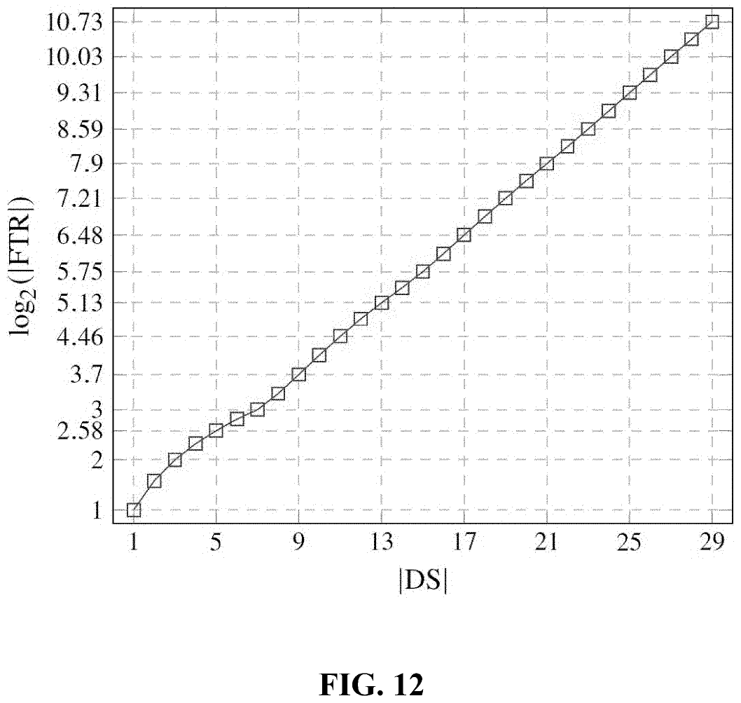

It is well worth mentioning that the relationship shown by FIG. 10 may also be approached from the perspective of information theory. If the vertical axis of FIG. 10 representing the FTR required for a given number of DS is made logarithmic, as in FIG. 12, then it reflects the amount of information (in bits) needed by the DS to avoid FS. From the correlation curve, it can be observed that for every DS added ≈0.35 bits of information is needed to avoid the appearance of FS using the technique proposed in this paper. This observation will also be useful in Sec. 5.4 when we show why no {c, u} coding schemes may exist for t>1.

### 4.6 Existence of Optimal {c, u} Coding Schemes with FTR

The number of FTRs required by a {c, u} coding scheme directly influences its complexity, and as shown in FIG. 10, |FTR| scales with |DS| exponentially. Moreover the larger parameters c and u get, the smaller the relative error correcting capabilities, expressed by t/u, the coding scheme has. For these two reasons alone it is apparent that c and u should be chosen to be as small as possible for a given implementation.

Earlier FIG. 6 showed all {c, u} coding schemes that satisfy the three basic existence criteria introduced in Sec. 3.2.3. According to that, the simplest candidate is the {14, 14} scheme. However this would leave at most [symbol] =5(c−2)−4u=4 bits for the SB, which would allow at most 13 FTRs (as shown by Table 3). However, FIG. 10 indicates that for the 11 complete DS in the {14, 14} code, 22 FTRs are required, and therefore, the {14, 14} coding scheme is insufficient.

Similar analysis can be performed on candidates of increasing complexity, and as shown in Table 4, the simplest {c, u} coding scheme that exists is {19, 19}. It is worth noting that the calculations under column “FTR possible” of this table follow the explanation in, and the values listed under, column “Number of signaling values” of Table 3, as well as the reasoning in Section 4.4. For example the number of possible FTRs for a {19, 19} coding scheme is listed as 13×7=91. In this calculation the value of 13 stems from the fact that the four bits referred to as S1-4 in FIG. 7 can encode this many distinct values, while avoiding an FS being formed, as explained in Table 3. The value of 7 in this calculation follows the explanation in Section 4.4, which shows that the five bits referred to as S5-9 in FIG. 7 can encode at most this many distinct values, while avoiding FS being formed by themselves and by any of the 2 PS.

TABLE 4
Existence of the Simplest {c, u} Coding Schemes with FTR

| | FTRs | | |
|---|---|---|---|
| {c, u} [symbol] | possible | required | May exist |
| {15, 15} 5 | 7 | 28 | No |
| {16, 16} 6 | | | |
| (17, 17} 7 | 3 × 7 = 21 | 35 | |
| {18, 18} 8 | 6 × 7 = 42 | 43 | |
| (19, 19} 9 | 13 × 7 = 91 | 54 | Yes |

From these it follows, that under the assumptions and using the techniques presented in this paper a {19, 19} coding scheme is optimal both from practical (engineering) and theoretical perspectives.

For other reasons one might choose to use a more complex implementable coding scheme. While these clearly diverge from the above-mentioned optimality, in return a more complex scheme would allow additional information to be encoded into the SB. For example, a {20, 20} coding scheme, would allow up to 29×7=203 (as per Table 3) possible FTRs, while only 69 of those would be required to avoid FS anywhere in the codeword. This allows └log₂(203/69)┘=1 free extra bit to be available to represent arbitrary information for every RS codeword, at a cost of decreasing the relative error correcting capability to one 5B symbol per twenty 5B symbols.

Following this thought pattern, it is apparent that using a {21, 21} coding scheme would make little sense, as the number of possible FTRs would still be 1×29×7=203 with an inferior relative error correcting capability compared to that of a {20, 20} coding scheme. Using the method described here, the relevant parameters of any arbitrary {c, u} coding scheme may be analyzed similarly.

### 4.7 An Example {19, 19} Coding Scheme

Previous sections showed the theoretical constructs behind {c, u} coding scheme. In this subsection we present the full details of an example {19, 19} coding scheme based on those, covering both encoding and decoding, by the direct application of all the methods described in Section 4.

For this example the field and code generator polynomials have been chosen according to Section 6.2.2, thus λ=3 and ω=2. The FS ‘X’ is selected to be represented by the decimal value 0, LSB is used to avoid FS among the PS, and the bits in the codeword are laid out according to FIG. 7. It is important to emphasize that all these choices are only to show a working example in our paper and an implementation is free to make different selections, for example for product-specific considerations. Due to the underlying construct any such scheme will correctly operate as long as all transmitters and receivers on a segment use the same constants.

A {19, 19} coding scheme incorporates 15 complete DS, which requires being able to encode 54 FTRs, as per FIG. 10. As shown by Table 3, a single 5B symbol can encode at most 29 values while avoiding FS, and therefore two 5B symbols formed by the SB will be needed to encode the 54 FTRs. This is done by breaking down each FTR into FTR_{high} (encoded by S5-9) and FTR_{low} (represented by S1-4) using, for example, the one-to-one mapping FTR=9(FTR_{high}−1)+FTR_{low}.

Under these conditions, it is clear that (5) and (6) simplify to P1=15a+7b+3s and P2=14a+6b+2s (respectively), from which it follows that:

P1_{left}=15a+7b

P2_{left}=14a+6b

[symbol]

₁(0)={2,4,6,8,10,12,14,17,19,21,23,25,27,29}

[symbol]

₁(1)={1,3,5,9,11,15,16,18,20,22,24,26,28,30}

[symbol]

₂(0)={1-6,8-12,14,15}

[symbol]

₂(1)={16-30}

Now, the lookup tables that map the admissible symbols can be laid out in the desired manner. In this example we do it using the most natural—incremental—approach, as follows:
Table 5: The 54 FTRs are assigned values in increasing order of FTR position and complexity;
Table 6: The 28 values used for transcoding FS among complete DS are assigned to fs−δ pairs so that fs keeps appearing in the order shown in Table 1, while δ increases sequentially;
Table 7: The nine values for FTR_{low} are assigned in increasing order; and
Table 8: Finally, the six values for FTR_{high} are assigned in increasing order, while maintaining the presence of values from [symbol] ₁(0), [symbol] ₁(1), [symbol] ₂(0), and [symbol] ₂(1) so that (5) can always be satisfied: for example in the group where FTR_{high}=1 1∈ [symbol] ₁(1) and [symbol] ₂(0), 2∈ [symbol] ₁(0) and [symbol] ₂(0), 16∈ [symbol] ₁(1) and [symbol] ₂(1), and 17∈ [symbol] ₁(0) and [symbol] ₂(1).

TABLE 5
An Example Assignment of FTRs and Meaning in a {19, 19} Coding

| FTR_{high} | FTR_{low} | FTR | A | B | FTR_{high} | FTR_{low} | FTR | A | B |
|---|---|---|---|---|---|---|---|---|---|
| 1 | 1 | 1 | — | | 5 | 1 | 37 | D3 | δ of 6^{th} += 1 × 7 |
| 1 | 2 | 2 | D1 | — | 5 | 2 | 38 | D4 | δ of 1^{st} += 1 × 7 |
| 1 | 3 | 3 | D2 | | . . . | | | | |
| | | | | | 5 | 6 | 42 | D4 | δ of 5^{th} += 1 × 7 |
| 1 | 9 | 9 | D8 | — | 5 | 7 | 43 | D5 | δ of 1^{st} += 1 × 7 |
| 2 | 1 | 10 | D9 | | . . . | | | | |
| 2 | 7 | 16 | D15 | | 6 | 1 | 46 | D5 | δ of 4^{th} += 1 × 7 |
| 2 | 8 | 17 | D1 | δ of 1^{st} += 1 × 7 | 6 | 2 | 47 | D6 | δ of 1^{st} += 1 × 7 |
| . . . | | | | | . . . | | | | |
| 3 | 6 | 24 | D1 | δ of 8^{th} += 1 × 7 | 6 | 4 | 49 | D6 | δ of 3^{rd} += 1 × 7 |
| 3 | 7 | 25 | D2 | δ of 1^{st} += 1 × 7 | 6 | 5 | 50 | D7 | δ of 1^{st} += 1 × 7 |
| | | | | | 6 | 6 | 51 | D7 | δ of 2^{nd} += 1 × 7 |
| 4 | 4 | 31 | D2 | δ of 7^{th} += 1 × 7 | 6 | 7 | 52 | D8 | δ of 1^{st} += 1 × 7 |
| 4 | 5 | 32 | D3 | δ of 1^{st} += 1 × 7 | 6 | 8 | 53 | D1 | δ of 1^{st} and |
| | | | | | | | | | 2^{nd} += 1 × 7 |

| | | | | | |
|---|---|---|---|---|---|
| . . . | 6 | 9 | 54 | D1 | δ of 1^{st} += 1 × 7 |

Legend of Table 5:
A: The first FS in the DS array;
B: Special treatment of some FS: adding multiples of 7 to their δ

TABLE 6
An Example Assignment of 5B Symbol Values and Transcoding Functions Usable
by DS of any {c, u}

| Binary, | | | Binary, | | | Binary, | | | Binary, | | |
|---|---|---|---|---|---|---|---|---|---|---|---|
| decimal | | | decimal | | | decimal | | | decimal | | |
| values | ƒ s | δ | values | ƒ s | δ | values | ƒ s | δ | values | ƒ s | δ |
| 00001, 1 | ‘T’ | EoL | 01010, 10 | ‘T’ | 2 | 10011, 19 | ‘T’ | 4 | 11011, 27 | ‘T’ | 6 |
| 00010, 2 | ‘R’ | | 01011, 11 | ‘R’ | | 10100, 20 | ‘R’ | | 11100, 28 | ‘R’ | |
| 00011, 3 | ‘I’ | | 01100, 12 | ‘I’ | | 10101, 21 | ‘I’ | | 11101, 29 | ‘I’ | |
| 00100, 4 | ‘X’ | | 01110, 14 | ‘X’ | | 10110, 22 | ‘X’ | | 11110, 30 | ‘X’ | |
| 00101, 5 | ‘T’ | 1 | 01111, 15 | ‘T’ | 3 | 10111, 23 | ‘T’ | 5 | | | |
| 00110, 6 | ‘R’ | | 10000, 16 | ‘R’ | | 11000, 24 | ‘R’ | | | | |
| 01000, 8 | ‘I’ | | 10001, 17 | ‘I’ | | 11001, 25 | ‘I’ | | | | |
| 01001, 9 | ‘X’ | | 10010, 18 | ‘X’ | | 11010, 26 | ‘X’ | | | | |

TABLE 7
An Example of 5B Symbol Values and FTR_{low} Usable by
S1-4 of a {19, 19} Coding Scheme

| Binary, | | Binary, | | Binary, | |
|---|---|---|---|---|---|
| decimal | | decimal | | decimal | |
| values | FTR_{low} | values | FTR_{low} | values | FTR_{low} |
| 0001, 1 | 1 | 0101, 5 | 4 | 1001, 9 | 7 |
| 0010, 2 | 2 | 0111, 7 | 5 | 1010, 10 | 8 |
| 0100, 4 | 3 | 1000, 8 | 6 | 1011, 11 | 9 |

TABLE 8
An Example Assignment of 5B Symbol Values and FTR_{high}
Usable by S5-9 of a {19, 19} Coding Scheme

| Binary, | | Binary, | | Binary, | |
|---|---|---|---|---|---|
| decimal | | decimal | | decimal | |
| values | FTR_{high} | values | FTR_{high} | values | FTR_{high} |
| 00001, 1 | 1 | 00101, 5 | 3 | 01010, 10 | 5 |
| 00010, 2 | | 00110, 6 | | 01011, 11 | |
| 10000, 16 | | 10100, 20 | | 11000, 24 | |
| 10001, 17 | | 10101, 21 | | 11001, 25 | |
| 00011, 3 | 2 | 01000, 8 | 4 | 01100, 12 | 6 |
| 00100, 4 | | 01001, 9 | | 01111, 15 | |
| 10010, 18 | | 10110, 22 | | 11010, 26 | |
| 10011, 19 | | 10111, 23 | | 11011, 27 | |

### 4.7.1 Encoding Process

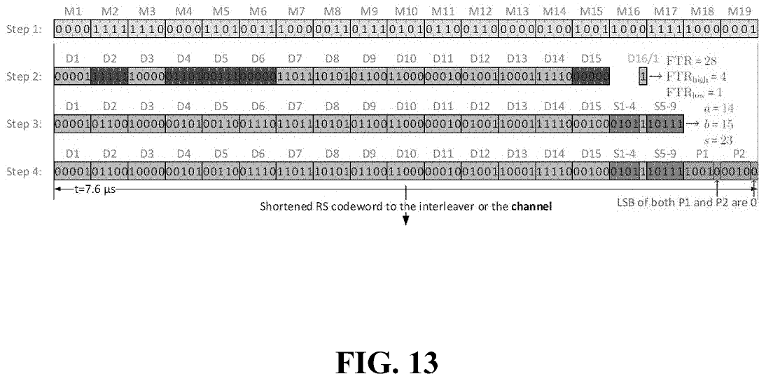

The example encoding shown by FIG. 13 consists of the following main steps:
1. First, u=19 user data 4B nibbles (MS) from the MAC/PLS interface are conveyed through the MII and collected by the encoder;
2. These are concatenated into 5B symbols (DS), FS are located and identified, determining the values for FTRs and providing FTR_{high} and FTR_{low};
3. All FS are transcoded using the linked list, S1-4 are filled in based on FTR_{low}, then a and b are calculated, which—in conjunction with FTR_{high}—is used to determine s, to be used directly by S5-9 in the codeword; and
4. All these are fed to the (19, 17) RS encoder, which provides the systematic RS codeword with 2t=2 PS.

The output codeword of this process can either be fed directly to the channel, or to the L-interleaver, to produce a superblock, which is then conveyed to the channel.

### 4.7.2 Decoding Process

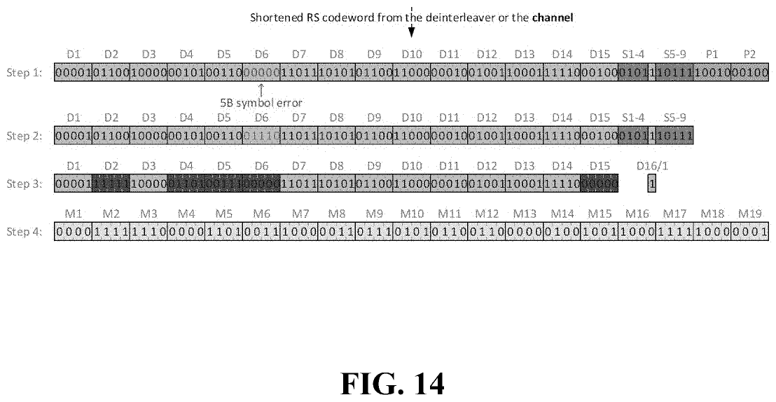

The example decoding shown by FIG. 14 is just an inversion of the encoding process shown in Section 4.7.1, thus is presented here only for the sake of completeness:
1. The codeword, with up to t=1 symbol error or 2t=2 symbol erasures, arrives from the channel or the L-deinterleaver;
2. It is fed to the RS decoder, which either corrects the error/erasures, or signals non-correctable errors/erasures (which can be used to provide higher overall error resilience), or if the quantity of these is beyond the known error correcting capability of the code it may do a miss-correction;
3. The FTR is decoded and the linked-list is walked to undo the FS transcoding applied by the encoder; and
4. Finally, the user data is separated into 4B nibbles (considering the framing in Section 5.1) and conveyed to the MAC/PLS interface via the MII.

This process is able to correct burst errors consisting of any combination of up to L consecutive 5B symbols.

### Section 5: Extensions to the Encoding Process

### 5.1 End of Sequence Delimiter Under FEC (FECESD)

As presented in Sec. 2.4.1, an additional 5B symbol value is reserved to allow reliable signaling of the end of frame. In the scope of this research, when the PCS Transmit function (PCS_TX) detects end of frame, it inserts this reserved symbol followed by an additional symbol indicating success or failure of frame transmission, analogous to the way a PPHY makes either BAD_ESD or GOOD_ESD follow DATA state (see FIG. 4).

As the proposed FEC relies on per-frame fixed size superblocks, codeword padding is applied after the symbol that follows FECESD. Given that the symbol following FECESD may have 28 different values, this technique allows the transmission of └log₂(2B/2)┘=3 additional bits of information, out of which one bit is used to indicate presence of symbol padding in the last 5B symbol, and every frame is terminated as follows:
If the bits embodying the received MS for the last codeword is not divisible by 5, then constant symbol padding is applied until this criterion is met;
A FECESD 5B symbol is inserted, followed by an admissible symbol indicating a good or bad ESD and the presence of symbol padding;
Codeword and superblock padding is/are applied as necessary;
Finally, the fixed 5B symbol sequence of ‘T’ followed by a ‘K’ is inserted to force all MACs above PPHYs to discard the frame, as described under Section 2.4.1.

For the reasons explained above, FECESD needs to be treated as an FS only when it appears among 5B symbols that form a complete DS. It may indeed appear among 5B symbols formed by SB, or those encoding PS.

### 5.2 Configurable Burst Length via Interleaving

With the channel model introduced in Section 1.2, the well-known technique of interleaving can be used to improve the burst error correction capabilities of the code according to known results (see, e.g., Pete Anslow, “RS(544,514) FEC performance with 4:1 interleaving,” August 2018, which is incorporated herein by reference in its entirety). When used with interleaving of depth L, the RS codeword of length=combines with the other interleaved RS codewords to form a superblock of length nL.

### 5.3 Erasure Correction

Erasure detection can rely on optional side-channel information provided by the receiver, whenever certain parameters of the received digital or analog signals are outside of the valid range. For example erasure may be assumed when the signal's swing, or DME timing is/are beyond a specified range (see Figure “147-13—DME encoding scheme” and Table “147-2—DME timings” in IEEE Std 802.3cg-2019), including tunable tolerances and margins.

### 5.4 {c, u} Coding Schemes for t>1

Until this subsection, we have discussed applicability of {c, u} coding schemes over GF(32) under the assumption that t=1, despite the fact that should any t>1 schemes exist, those may provide improvement to the relative error correcting capabilities. This subsection focuses on this undiscussed area of the solution candidate space, and shows that no {c, u} coding schemes exist beyond t=1.

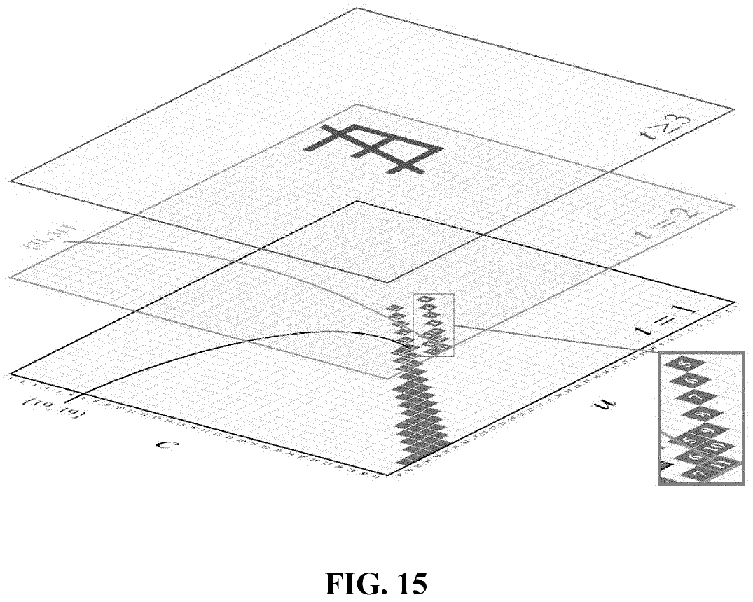

To achieve this, the system of three inequalities presented in Section 3.2.3 for t>1, the output of which is visualized by FIG. 15. Following the color-coding of FIG. 6, the green squares represent the {c, u} coding scheme candidates that meet the necessary conditions, while the red coloring was omitted for clarity. What is immediately apparent here is that solution candidates exist for t=2, but the space for t≥3 is void of solutions.

As explained in Section 3.2.3, [symbol] =5(c−2t)−4u represents the number of bits available among the SB to encode FTR and to avoid FS among the PS. This is the factor that essentially decides whether a solution candidate may lead to an actual solution. FIG. 15 shows that t=2 offers ten solution candidates, the values of [symbol] for which are shown by the white numbers in the green carets. The value for [symbol] is largest for {31, 31}. Therefore, if it is shown that these [symbol] =11 bits are insufficient for a {31, 31} coding scheme to exist, it follows that none of the remaining nine candidates may lead to a solution either. This is because increasing u decreases [symbol] , while decreasing c does not free up even a single complete bit, as stated in Section 4.5.

In each {c, u} coding scheme, the number of PS is 2t, thus for t=2 the scheme has to avoid FS for 4 PS. This will require 4 bits, and therefore a complete 5B symbol, as shown in Table 3, to encode four parametric partitionings. ( [symbol] ₁- [symbol] ₄). This is an extension of the 2 parametric partitionings for t=2 discussed in Section 4.4. Moreover, an additional bit is needed to avoid D25 from being an FS. This leaves 11−5−1=5 bits among the SB available to encode the 494 FTRs necessitated by the 24 complete DS in this scheme, as shown in FIG. 10. As 5 bits can encode at most 29 values without using FS, encoding 494 FTRs is not possible, which leads to the conclusion that no {c, u} coding schemes exist for t>1.

### Section 6: Analysis

In this section, an analysis is conducted of the applicability, some of the characteristics, and the performance of the disclosed scheme.

In general, systematic error correcting codes have the advantage of being encodable “on-the-fly”: when the data arrives, the encoder can already start forming the codewords, producing output without delay. However in the case proposed herein, this does not stand. The reason for this is three-fold:
The user input data concatenation process depicted in FIG. 5 causes a short delay in the output stream: e.g. to be able to create D12, M15 must be received;
The escaped elements of the FS linked list and the values of SB may be formed only when the last 4B symbol arrives from MII;
If interleaving is applied, it imposes an additional (fixed) delay, as the channel input can be formed only after the RS codewords at the interleaver's inputs are available.

An upper bound on the total delay caused by these factors is 5cL+ϵ, bit times, where ϵ denotes the implementation-dependent encoding and decoding delays in the silicon, and 5cL is the size of the superblock in time domain

In contrast, for a PPHY that works without FEC and relies on retransmissions, the lower bound for these delays is the total transmission time for the packet. In the case of Ethernet this is 512 bit times, in addition to the delays imposed by the higher layers carrying out the retransmissions. The packet retransmission delays are—typically several magnitudes—larger than the delays attributed to the scheme proposed herein with any reasonable value for L, irrespective of whether the higher layers use a positive or a negative acknowledgement scheme for triggering a retransmission.

Additionally, actual implementations hiding or incorporating the MII interface may partially or completely eliminate encoding and decoding delay, benefitting the proposed scheme.

### 6.1 Verification of the Results

To verify the performance of the proposed FEC scheme claimed in this application, this research has implemented the complete encoding and decoding scheme over configurable field- and code-generator polynomials. An exhaustive test over the extended field GF(32) defined by the field generator polynomial of p(x)=x⁵+x²+1, and the code generator polynomial of g(x)=(x+a^{c}(x+a^{c+1})=x²+3x+2 (for c=0) has been performed using the {19, 19} coding scheme over a (19, 17) systematic RS code, based on the algorithm presented in this specification, while the choice of actual 5B symbol values was done according to Section 4.7.

These exhaustive simulations have run without errors, showing that scheme proposed in this paper is both implementable and working as theory suggests.

In the presented pseudo-code, a set of specific functions are used, as shown herein:
generate_76_DS_bits(s): produce 75+1=76 bits of concatenated MII data (MS), according to the algorithm shown below:

```
function generate_76_DS_bits(s: uint)
    5B retval_DS[15]
    uint _s
    5B _v
    for i in 0..14:
        if i≠0: _s:=s/5\hat{ }i
        else: _s:=s
        switch _s
          0: _v:=I
          1: _v:=T
          2: _v:=R
          3: _v:=Q
        otherwise:_v:=rnd(1-31)
    retval_DS[i]:= _v
return concatenate(retval_DS, rnd(0-1))
```

linked_list_encode( ) and linked_list_decode( ): encoding and decoding as described under “3.4.A Forbidden symbols among DS: recoding FS values through a linked list”;
generate_9_SB_bits( ): encoding technique described under “3.4.B Forbidden symbols among PS: avoiding FS values”;
FS_exists( ): verification whether FS values appear in the input's 5B domain;
add_error( ): injection of a non-zero error to a given 5B symbol positions;
stop( ): terminate execution with error or success.

Based on this, the algorithm used for the end-to-end verification of the proposed novel scheme is as follows:

```
for s in 0..((5\hat{ }15)-1):
    DS_raw:=generate_76_DS_bits(s)
    DS, SB_raw:=linked_list_encode(DS_raw)
    SB:=generate_9_SB_bits(DS, SB_raw)
    codeword_in:=RS_encode(DS, SB)
    if FS_exists(codeword_in): stop(ERROR)
    for e in 1..20:
        codeword_out:=codeword_in
        if e≠1: add_error(codeword_out, e-1)
        codeword_est:=RS_decode(codeword_out)
        DS_est:=linked_list_decode(codeword_est)
        if DS_est≠DS_raw: stop(ERROR)
stop(SUCCESS)
```

As visible, this will result in 5¹⁵≈3×10¹⁰ encoding and 5¹⁵×20≈6.1×10¹¹ decoding cycles. This simulation has run without errors, ending in stop(SUCCESS), showing the scheme proposed in this specification to be implementable and working as theory suggests.

### Section 7: Conclusion

This specification has shown that it is possible to design and implement low-complexity, backward compatible FEC using the novel combination of an RS FEC scheme, a linked-list-based technique to skip forbidden symbols in the MII data part of the codeword, and a lightweight linear coding technique that guarantees the same for the signaling and parity symbols.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for communicating data over a mixing segment of an Ethernet network, in particular over an Ethernet network segment, by using node A and node B communicatively connected to the mixing segment,
wherein the method comprises:
generating, by node A, an Ethernet frame E addressed to a node B,
applying, by node A, a Reed-Solomon -type encoding to the Ethernet frame E to generate an encoded Ethernet frame E′,
transmitting, by node A, the encoded Ethernet frame E′ over the mixing segment
receiving, by node B, from the mixing segment the encoded Ethernet frame E′,
applying, by node B, a Reed-Solomon -type decoding to the Ethernet frame E′ to obtain a forward error correction representative of the original Ethernet frame E,
wherein applying a Reed-Solomon-type encoding comprises:
generating a list of forbidden symbols FS,
when applying the Reed-Solomon control symbols to the Ethernet frame E, removing or blocking the forbidden symbols FS from the encoded Ethernet frame E′.

2. The method according to claim 1, wherein the list of forbidden symbols FS comprises:

| Name | 5B | Special function |
|---|---|---|
| I | 11111 | SILENCE |
| T | 01101 | ESD/HB |
| R | 00111 | ESDOK/ESDBRS |
| Q | 00000 | FECESD |

3. An Ethernet bus node, which comprises a MAC and a PHY, wherein the Ethernet node is configured to run the method of claim 1.

4. The Ethernet bus node according to claim 3, wherein the Ethernet bus node is configured to communicate over a mixing segment, in particular over a 10BASE-T1S Ethernet network segment.

5. The Ethernet bus node according to claim 4, wherein the mixing segment comprises a single-pair cable, such as a twisted-pair cable, and the transceiver circuit of the Ethernet bus node is configured to be connected to the cable.

6. A method of communicating data over a network, comprising:
generating, by a first node, a frame addressed to a second node;
encoding, by the first node, the generated frame by applying forward error correction (FEC) coding on the generated frame in such manner that blocks or removes a predetermined set of forbidden symbols (FS) from the encoded frame; and
transmitting, by the first node, the encoded frame to the second node.

7. The method of claim 6, wherein
the encoding of the generated frame includes encoding a FS transcoding recipe (FTR) as a linked list of the forbidden symbols and using the encoded FTR to eliminate the forbidden symbols among parity symbols.

8. The method of claim 6, wherein
the encoding of the generated frame includes a mapping of symbols in the frame, said mapping having an inherent redundancy.

9. The method of claim 6, wherein the FEC coding uses block codes.

10. The method of claim 6, wherein the FEC coding uses a systematic code, in particular a Reed-Solomon code.

11. The method of claim 6, wherein the FEC coding is defined over a finite field of GF(32).

12. The method of claim 11, wherein the field of GF(32) is defined by the field generator polynomial of p(x)=x⁵+x²+1, and the code generator polynomial of g(x)=(x+a^{c}) (x+a^{c+1}).

13. The method of claim 6, wherein the predetermined set of forbidden symbols includes

| Symbol | Mapped | |
|---|---|---|
| Name | Binary Value | Function |
| I | 11111 | SILENCE |
| T | 01101 | ESD/HB |
| R | 00111 | ESDOK/ESDBRS |
| Q | 00000 | FECESD |

14. The method of claim 6, wherein
the second node comprises a PHY configured according to Clause 147 of the IEEE 802.3cg standard,
the first node encodes each FEC frame in such manner that causes the PHY of the second node to transition from state DATA to state WAIT_SYNC through state BAD_ESD, thereby causing the PHY to drop the FEC frame without propagating data of the FEC frame to a MAC of the second node.

15. The method of claim 6, wherein the FEC coding uses interleaving.

16. An Ethernet bus node, which comprises a MAC and a PHY, wherein the Ethernet node is configured to run the method of claim 2.

17. The method of claim 7, wherein
the encoding of the generated frame includes a mapping of symbols in the frame, said mapping having an inherent redundancy.

18. The method of claim 7, wherein the FEC coding uses block codes.

19. The method of claim 8, wherein the FEC coding uses block codes.

20. The method of claim 7, wherein the FEC coding uses a systematic code, in particular a Reed-Solomon code.
